(19) United States
(12) Patent Application Publication
(10) Pub. No.: US 2017/0213801 A1
(43) Pub. Date: Jul. 27, 2017

(54) METHOD FOR MANUFACTURING A PACKAGE-ON-PACKAGE ASSEMBLY

(71) Applicant: Micron Technology, Inc., Boise, ID (US)

(72) Inventors: Tieh-Chiang Wu, Taoyuan City (TW); Shing-Yih Shih, New Taipei City (TW)

(21) Appl. No.: 15/003,812

(22) Filed: Jan. 22, 2016

(51) Int. Cl. H01L 23/00; H01L 21/56; H01L 23/31; H01L 21/78

(52) U.S. Cl. CPC H01L 24/02; H01L 21/78; H01L 21/565; H01L 23/3171; H01L 2224/024; H01L 2224/02373; H01L 2224/0235; H01L 2224/02333; H01L 2224/02331; H01L 2224/0231

(57) ABSTRACT

A method for fabricating a package-on-package assembly is provided. A carrier with a passivation layer on the carrier is provided. A redistribution layer (RDL) is formed on the passivation layer. The RDL comprises at least one dielectric layer and at least one metal layer. The at least one metal layer comprises a plurality of first bump pads and second bump pads exposed from a top surface of the at least one dielectric layer. The first bump pads are disposed within a chip mounting area, while the second pads are disposed within a peripheral area. At least one chip is then mounted on the first bump pads. The at least one chip is electrically connected to the RDL through first bumps on the first bump pads. A die package is then mounted on the second bump pads. The die package is electrically connected to the RDL through second bumps on the second bump pads.

### TECHNICAL FIELD

The present invention relates generally to the field of semiconductor packaging, and, more particularly, to a method for manufacturing a Package-on-Package (PoP) assembly.

### BACKGROUND

With recent advancements in the semiconductor manufacturing technology, microelectronic components are becoming smaller and circuitry within such components is becoming increasingly dense. To reduce the dimensions of such components, the structures by which these components are packaged and assembled with circuit boards must become more compact.

As known in the art, fan-out wafer-level packaging (FOWLP) is a packaging process in which contacts of a semiconductor die are redistributed over a larger area through a redistribution layer (RDL) that is typically formed on a substrate such as a TSV interposer. The TSV interposer is costly because fabricating the interposer substrate with TSVs is a complex process.

The RDL is typically defined by the addition of metal and dielectric layers onto the surface of the wafer to re-route the I/O layout into a looser pitch footprint. Such redistribution requires thin film polymers such as benzocyclobutene (BCB), polyimide (PI), or other organic polymers and metallization such as Al or Cu to reroute the peripheral pads to an area array configuration.

In order to meet the requirements of smaller footprints with higher densities, three-dimensional (3D) stacking packaging such as PoP (Package-on-Package) assembly has been developed. A PoP assembly typically includes a top package with a device die bonded to a bottom package with another device die. In PoP designs, the top package may be interconnected to the bottom package through peripheral solder balls.

### BRIEF SUMMARY

It is one object of the invention to provide an improved method for fabricating a Package-on-Package (PoP) assembly, which is cost-effective.

In one aspect of the present invention, a method for fabricating a package-on-package assembly is provided. A carrier with a first passivation layer on the carrier is provided. A redistribution layer (RDL) is formed on the first passivation layer. The RDL comprises at least one dielectric layer and at least one metal layer. The metal layer comprises a plurality of first bump pads and second bump pads exposed from a top surface of the dielectric layer. The first bump pads are disposed within a chip mounting area, while the second bump pads are disposed within a peripheral area around the chip mounting area. At least one chip is then mounted on the first bump pads. The chip is electrically connected to the RDL through a plurality of first bumps on the first bump pads. A die package is then mounted on the second bump pads. The die package is electrically connected to the RDL through a plurality of second bumps on the second bump pads.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIG. 1 through FIG. 7 are schematic diagrams showing an exemplary method for fabricating a Package-on-Package (PoP) assembly according to one embodiment of the invention.

### DETAILED DESCRIPTION

In the following detailed description of the invention, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments may be utilized and structural changes may be made without departing from the scope of the present invention.

The following detailed description is, therefore, not to be taken in a limiting sense, and the scope of the present invention is defined only by the appended claims, along with the full scope of equivalents to which such claims are entitled. One or more implementations of the present invention will now be described with reference to the accompanying drawings, wherein like reference numerals are used to refer to like elements throughout, and wherein the illustrated structures are not necessarily drawn to scale.

The present invention pertains to a “RDL-first” process for making a first package. A second package is mounted onto the first package in a chip-to-wafer fashion (Wafer-level PoP).

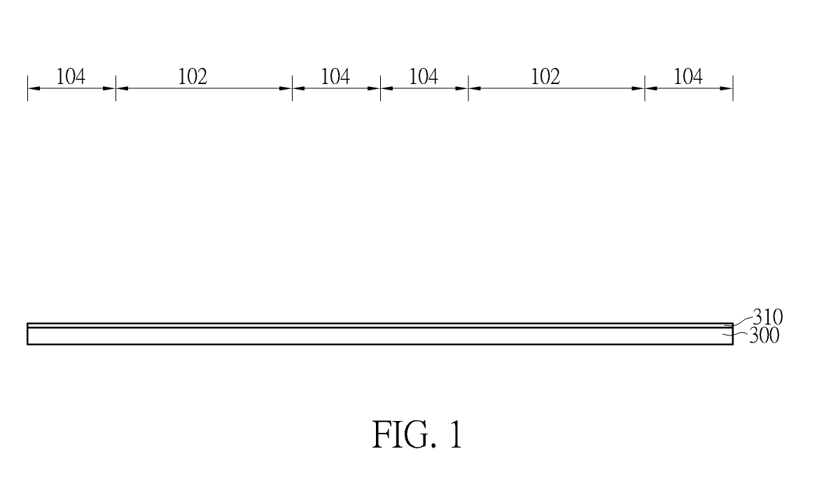

FIG. 1 through FIG. 7 are schematic diagrams showing an exemplary method for fabricating a Package-on-Package (PoP) assembly according to one embodiment of the invention. As shown in FIG. 1, a carrier 300 is prepared. The carrier 300 may be a releasable substrate material or wafer with an adhesive layer (not explicitly shown), but is not limited thereto. At least a dielectric layer or a passivation layer 310 is then formed on a top surface of the carrier 300. The passivation layer 310 may comprise organic materials such as polyimide (PI) or inorganic materials such as silicon nitride, silicon oxide or the like.

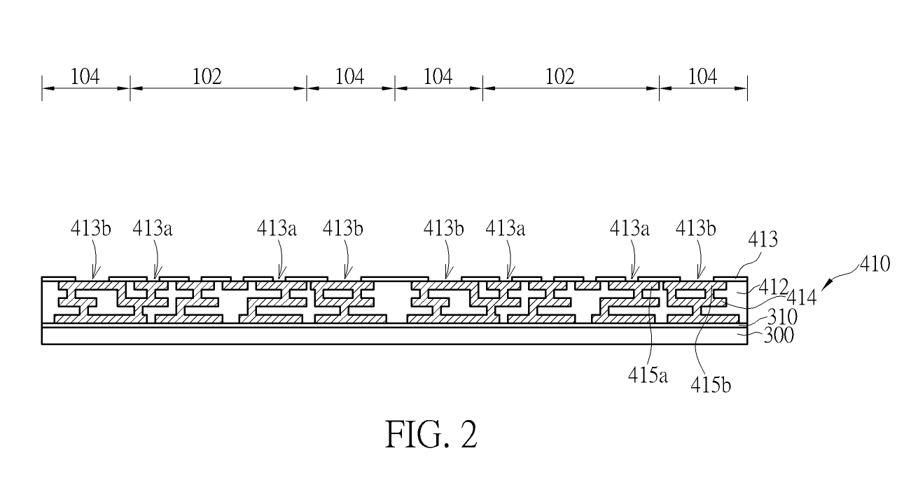

As shown in FIG. 2, subsequently, a redistribution layer (RDL) 410 is formed on the passivation layer 310. The RDL 410 may comprise at least one dielectric layer 412 and at least one metal layer 414. The dielectric layer 412 may comprise organic materials such as polyimide (PI) or inorganic materials such as silicon nitride, silicon oxide or the like, but is not limited thereto. The metal layer 414 may comprise aluminum, copper, tungsten, titanium, titanium nitride, or the like.

According to the illustrated embodiment, the metal layer 414 may comprise a plurality of first bump pads 415a and second bump pads 415b exposed from a top surface of the dielectric layer 412. The first bump pads 415a are disposed within a chip mounting area 102, while the second bump pads 415b are disposed outside the chip mounting area, such as a peripheral area 104 around the chip mounting area 102.

Subsequently, a passivation layer 413 such as polyimide or solder mask material may be formed on the dielectric layer 412. The passivation layer 413 may include first openings 413a and second openings 413b that expose respective first and second bump pads 415a and 415b.

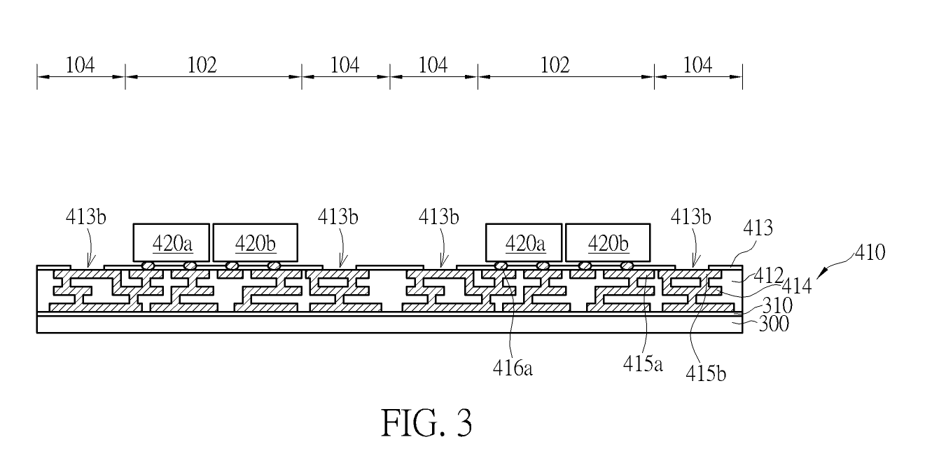

As shown in FIG. 3, a conventional electroplating solder bumping process may be performed to form first bumps 416a on the respective first bump pads 415a. Individual flip-chips or dies 420a and 420b with their active sides facing down toward the RDL 410 are then subsequently mounted on the RDL 410 through the first bumps 416a to thereby form a stacked chip-to-wafer (C2W) construction. These individual flip-chips or dies 420a and 420b are active integrated circuit (IC) chips with certain functions, for example, GPU (graphics processing unit), CPU (central processing unit), memory chips, etc. Optionally, an underfill (not shown) may be applied under the chips 420a and 420b.

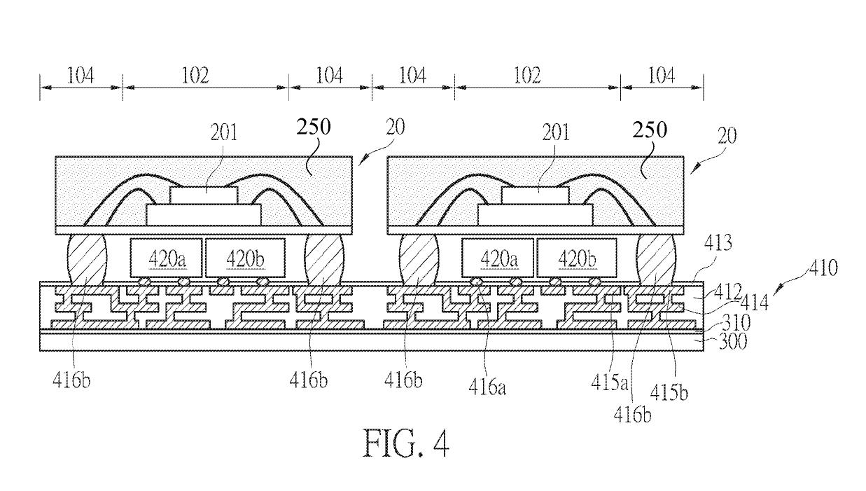

As shown in FIG. 4, a die package 20 comprising at least a molded semiconductor die 201 is mounted on the RDL 410 in a wafer level manner. The die package 20 comprises a molding compound 250. The die package 20 may be electrically connected to the RDL 410 through the second bumps 416b. The second bumps 416b are formed in the openings 413b and on the second bump pads 415b. The second bumps 416b have a height that is greater than the thickness of the chip 420a or chip 420b. It is understood that the second bumps 416b may be bumps formed on the lower surface of the die package 20, copper pillars, or bumps formed by a ball drop method, but is not limited thereto.

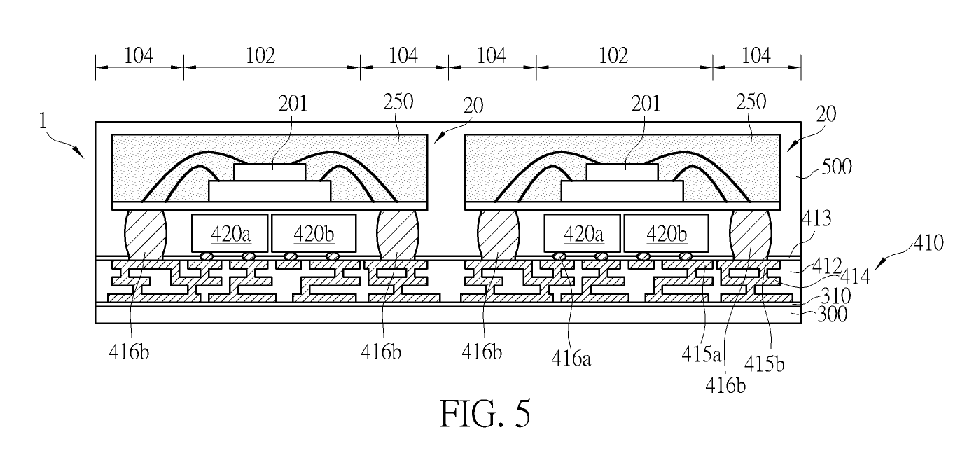

As shown in FIG. 5, after mounting the die package 20 on the RDL 410, a molding compound 500 is applied. The molding compound 500 at least covers the die package 20, the chips 420a and 420b, the second bumps 416b, and the top surface of the RDL 410, thereby forming a wafer-level PoP 1. The molding compound 500 may be subjected to a curing process. The curing process may be carried out at a temperature that is lower than the glass transition temperature (Tg) of the molding compound 250. The molding compound 500 may comprise a mixture of epoxy and silica fillers, but is not limited thereto. The molding compound 250 and the molding compound 500 may have different compositions so that the molding compound 500 may be cured at relatively lower temperatures. Optionally, a grinding process may be performed to polish away a top portion of the molding compound 500.

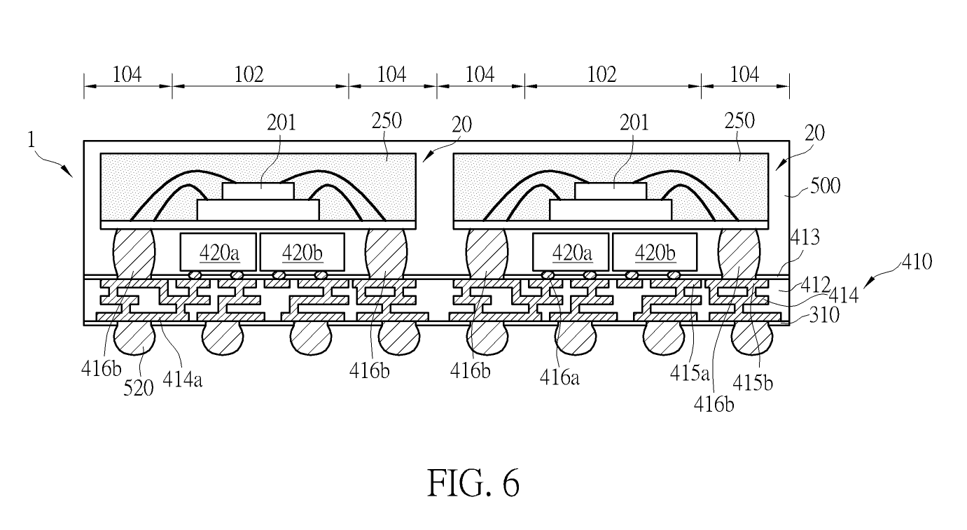

Subsequently, as shown in FIG. 6, the carrier 300 is removed to thereby expose a major surface of the passivation layer 310. The de-bonding of the carrier 300 may be performed by using a laser process or UV irradiation process, but is not limited thereto. After de-bonding the carrier 300, openings may be formed in the passivation layer 310 to expose respective solder pads 414a, and then solder bumps or solder (C4) balls 520 may be formed on the respective solder pads 414a.

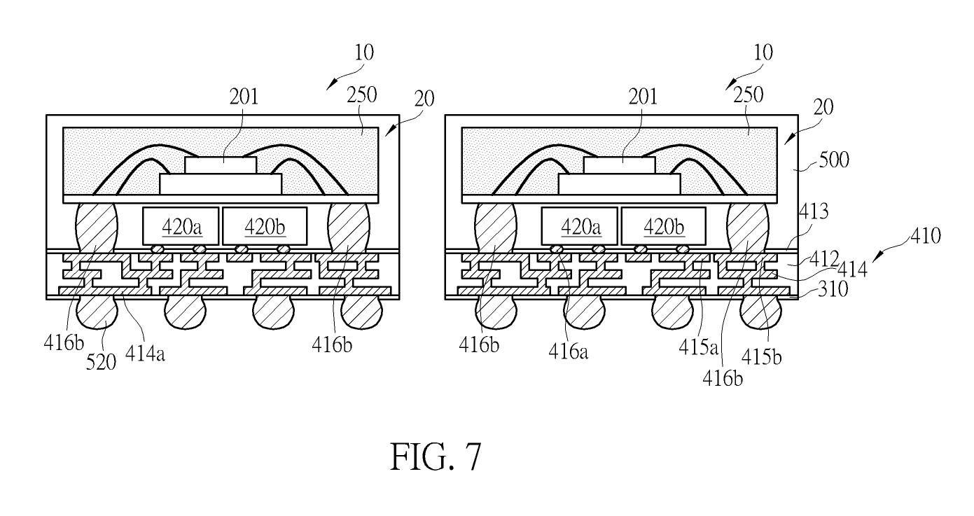

As shown in FIG. 7, a dicing process is performed to singulate individual Package-on-Package (PoP) assemblies 10. During the dicing process, a dicing tape (not shown) may be used to provide temporary support, and the solder balls 520 may be adhered to the dicing tape.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a package-on-package (PoP) assembly, comprising:
providing a carrier with a first passivation layer on the carrier;
forming a redistribution layer (RDL) on the first passivation layer, wherein the RDL comprises at least one dielectric layer and at least one metal layer, wherein the at least one metal layer comprises first bump pads and second bump pads exposed from a top surface of the at least one dielectric layer, wherein the first bump pads are disposed within a chip mounting area, and the second bump pads are disposed within a peripheral area around the chip mounting area;
mounting at least one first chip on the first bump pads, wherein the at least one first chip is electrically connected to the RDL through first bumps on the first bump pads;
mounting a die package comprising at least one second chip pre-encapsulated in a first molding compound on the second bump pads, wherein the die package is electrically connected to the RDL through second bumps on the second bump pads; and
encapsulating the die package, the at least one chip, and the RDL in a second molding compound and curing the second molding compound at a temperature lower than a glass transition temperature of the first molding compound.

2. The method for fabricating a PoP assembly according to claim 1, wherein before mounting the at least one chip on the first bump pads, the method further comprises:
forming a second passivation layer on the at least one dielectric layer;
forming first and second openings in the second passivation layer to expose respective first and second bump pads; and
forming the first bumps on the respective first bump pads.

3. The method for fabricating a PoP assembly according to claim 1, wherein after mounting the die package on the second bump pads, the method further comprises:
de-bonding the carrier to thereby expose a major surface of the first passivation layer;
forming solder balls in or on the first passivation layer; and
performing a dicing process to singulate individual package-on-package assemblies.

4. The method for fabricating a PoP assembly according to claim 1, wherein providing the first passivation layer comprises providing an organic material.

5. The method for fabricating a PoP assembly according to claim 4, wherein providing the organic material comprises providing a polyimide.

6. The method for fabricating a PoP assembly according to claim 1, wherein providing the first passivation layer comprises providing an inorganic material.

7. The method for fabricating a PoP assembly according to claim 1, wherein providing the inorganic material comprises providing silicon nitride or silicon oxide.

8. The method for fabricating a PoP assembly according to claim 1, wherein forming the redistribution layer comprising the at least one metal layer comprises forming the redistribution layer comprising at least one layer of aluminum, copper, tungsten, titanium, or titanium nitride.

9. The method for fabricating a PoP assembly according to claim 2, wherein forming the second passivation layer comprises forming polyimide or a solder mask material.

10. The method for fabricating a PoP assembly according to claim 1, wherein mounting the die package comprises mounting a die package comprising second chips pre-encapsulated in the first molding compound.

11. A package-on-package (PoP) assembly, comprising:
a first passivation layer;
a redistribution layer (RDL) on the first passivation layer wherein the RDL comprises at least one dielectric layer and at least one metal layer, wherein the at least one metal layer comprises first bump pads and second bump pads exposed from a top surface of the at least one dielectric layer, wherein the first bump pads are disposed within a chip mounting area, and the second bump pads are disposed within a peripheral area around the chip mounting area;
at least one chip mounted on the first bump pads, wherein the at least one chip is electrically connected to the RDL through first bumps on the first bump pads;
a die package on the second bump pads, wherein the die package is electrically connected to the RDL through second bumps on the second bump pads, and wherein the die package comprises a first molding compound; and
a second molding compound encapsulating the die package and the RDL, the second molding compound having a curing temperature lower than a glass transition temperature of the first molding compound.

12. The package-on-package (PoP) assembly according to claim 11, further comprising:
a second passivation layer on the at least one dielectric layer; and
first openings and second openings in the second passivation layer to expose respective first and second bump pads.

13. The package-on-package (PoP) assembly according to claim 11, wherein the first molding compound and the second molding compound have different compositions.
